(19) United States
(12) Patent Application Publication
(10) Pub. No.: US 2025/0279754 A1
(43) Pub. Date: Sep. 4, 2025

(54) Integrated Bi-Directional Amplifier

(71) Applicants: Vimal Dutt, Secaucus, NJ (US); Williams Vasquez, Fair Lawn, NJ (US)

(72) Inventors: Vimal Dutt, Secaucus, NJ (US); Williams Vasquez, Fair Lawn, NJ (US)

(21) Appl. No.: 18/753,998

(22) Filed: Jun. 25, 2024

Related U.S. Application Data
(60) Provisional application No. 63/559,744, filed on Feb. 29, 2024.

(51) Int. Cl. H03F 3/24; H03F 3/189

(52) U.S. Cl. CPC H03F 3/245; H03F 3/189; H03F 2200/451

(57) ABSTRACT

A unified, integrated bi-directional Radio Frequency (RF) amplifier comprising a unitary housing having walls adapted to allow communication therethrough, a power amplifier, a RF signal filter and an internal electrical backup power source, wherein the power amplifier, the radio frequency filter and the internal electrical backup power source are integrated within a BDA all enclosed by the unitary housing. In one embodiment, the internal electrical backup power source is a lithium-ion battery or battery array. In another embodiment, the amplifier may be electrically coupled to an external power source and to an internal backup power supply.

### CROSS REFERENCE TO RELATED APPLICATIONS

This is a non-provisional application of Provisional Patent Application Ser. No. 63/559,744, filed Feb. 29, 2024, the entire specification of which is herein incorporated by reference.

### BACKGROUND OF THE INVENTION

### 1. Field of the Invention

This invention relates generally to an integrated radio frequency (RF) amplifier and more specifically to an integrated RF amplifier providing an integrated, unified, standalone RF amplifier system having an internal power source.

### 2. Background Art

As a result of miscommunications and lack of interoperability between radio and other communications, the first responders in the 9-11 disaster were unable to smoothly and efficiently communicate with each other. This was especially true when such communications were required between first responders of different organizations, for example, between municipal and federal agents, and even between different organizations of the same municipality, such as the police and fire brigades. Subsequently, many agencies, both federal and municipal have required systems be implemented that would render as integrated as possible and standardize such emergency communications. These communications systems for the most part have been implemented in the intervening period, and have been required to meet several standards, including federal communications, municipal regulations and building codes. Many of these types of integrated communications systems require that any signals be secure and amplified to enable clear and immediate communications. Thus, bi-directional amplifiers were proposed and introduced to meet these challenges.

High frequency modules have recently become available for amplification of transmission signals. For example, U.S. Pat. No. 10,804,955 teaches such a system which includes a signal transmission amplifier that outputs a transmission signal to an antenna terminal side, a reception signal amplifier that amplifies a reception signal supplied from an antenna terminal, a switch that selectively connects the antenna terminal to either an output of the transmission signal amplifier or an input of the reception signal amplifier and a directional coupler that is provided on a transmission signal path and detects a signal level of the transmission signal. The transmission signal amplifier is controlled by a first control signal supplied from a first control circuit. The reception signal amplifier is controlled by a second control signal supplied from a second control circuit. The switch is controlled by a switch control signal supplied from the first control circuit. The directional coupler is controlled by a coupler control signal supplied from the first control circuit.

Japanese Patent No. 7,381,261 entitled “Wireless Base Station Equipment and Wireless Network System” teaches a reception-only side switch provided between a reception-only antenna and a second high-frequency low-noise amplifier. Switch control provides that the reception-only side switch is cut off when a transmission/reception side switch unit is in the transmission connection state, the system designed to protect a high frequency low noise amplifier included in a reception circuit on the receive-only antenna side from damage caused by wraparound reception of transmitted waves even when the transmission power is set large in a wireless base station device.

U.S. Published Patent Application No. 2006/0035600A1 discloses a switching mechanism for a wireless communication system using Radio Frequency (RF) signals. In the RF front-end apparatus, a detector is provided at a predetermined position in a signal path, and detects a signal propagating therein. A circulator provides a signal received from a power amplifier to an antenna feed line and a signal received from the antenna feed line to a switch. A switch controller generates a control signal based on the signal received from the detector and a switch on/off signal received from a control board. The switch is disposed at an input port of a low noise amplifier, switches on/off according to the control signal received from the switch controller. For purposes of the operational capabilities of as Distributed Antenna Systems (DAS) according to this invention, the disclosures of the above-described known systems are incorporated by reference, where appropriate, as if they were fully set forth herein.

Presently known Distributed Antenna Systems (DAS) require at least two modules that must be interconnected by qualified installers having the necessary experience. Such DAS Systems are provided to enhance communications by emergency personnel at a specific location that requires capabilities for continuous and consistent communications and environmental monitoring and instantaneous communications and condition updating of environmental status of sensors that are in communication with the DAS. Installation of the DAS must be faultless and the system must work to specifications (federal, industry and municipal) and must comply with regulations (e.g., building or fire codes). Under normal circumstances, the installation of a DAS system of this type requires at least two installers who are knowledgeable of the different modules that are going to be interconnected.

A bi-directional amplifier (BDA) is normally operable and communicably coupled via signal feed from, e.g., a cell tower, and via distribution network in a wireless environment such as LMR (land mobile radio) or cellular installation or non-wireless such as fiber distributed solution, e.g., BDAs containing head end fiber transceivers (RF to light) and annunciator panels. The technology is normally used in remote fiber transceivers (light to RF) across the specified power and frequency range amplified by the BDA/Fiber transceiver unit. For example, the DAS may provide distributed communication to persons and/or fire safety apparatus (e.g., a fire safety control panel) throughout a building and/or environment including outdoor and underground locations as fixed or mounted mobile units. For example, the communication may be reserved for first responders (e.g., fire, police, medical responders) or other safety control or regulating bodies.

Referring now to FIGS. 1 and 2 there are illustrated two known block diagrams of the configurations of both the presently known DAS and of the inventive integrated technology distributed antenna systems as shown. The DAS structure or enclosure is capable of being installed in a variety of locations and for uses where a boost in a radio frequency signal is required.

Shown in FIG. 1 is a known configuration of a Wireless Distribution DAS Installation 20 showing several separate modules, including the Bi-Directional Amplifier (BDA) electronics module 22, the Back Up Lead Acid Batteries module 24 for providing external source of backup power in the event that the primary electrical power is interrupted, the annunciator module 26, built into the BDA or BBU, for indicating conditions and providing control of the system, the Fire control alarm control panel (FACP) 28 for providing alarms and for displaying the module alarm conditions and an off-site Remote Annunciator Panel module 29 for providing remote control access and monitoring capabilities to the system. The necessary connections and communication means between these modules are omitted for ease in illustration.

FIG. 2 illustrates a similar Distribution DAS Installation configuration 30 when external communications are conducted through fiber optical fibers (schematically shown as module 32). Because the structures and operations of the modules 34 (the Fiber Head End), 24, 26, 28 and 29 are in most respects identical, the same numbers are used. Where a difference exists in the modules, for example, in the fiber optical cabling provided by module 32, a different number is used. As shown in FIG. 2, the BDA Fiber remotes module 32 includes fiber optic connectors and cabling, and one or more fiber bi-directions transceivers, as will be described below with reference to FIGS. 20, 21 and 22.

However, all of the known systems require several modules, including separate freestanding second or third modules e.g., battery backup modules 24, to provide, for example, a backup power source in the event of a power outage or disruption. These separate modules must be connected to each other through dedicated electrical and/or optical fiber connections that must be integrated into a complete system capable of efficient operation, all the while meeting federal, municipal and technical requirements and specifications. Connections of such system modules is cumbersome, inefficient and in many instances calls for two or more installers, each having separate areas of expertise, who must work in tandem to ensure precise and code compliant connections to primary power, secondary power, other modules and to fire alarm control panels.

None of the prior art devices methods known heretofore teach the inventive combination of several elements in an integrated, unified, standalone RF amplifier system having an internal power source all enclosed in a single housing, thereby requiring only a minimum of external communication and power supply connections, the installations of which will require installation that is simpler, more efficient and safer than heretofore known and that would require at most two installers who can work independently to safely and efficiently install the Distributed Antenna Systems according to the present invention.

### SUMMARY OF THE INVENTION

Accordingly, there is described and claimed herein a unified, integrated bi-directional Radio Frequency (RF) amplifier comprising a unitary housing having walls adapted to allow communication therethrough, a power amplifier, a RF signal filter and an internal electrical backup power source, wherein the power amplifier, the radio frequency filter and the internal electrical backup power source are integrated within a distributed antenna system all enclosed by the unitary housing. In one embodiment, the internal electrical backup power source is a lithium-ion battery or battery array. In another embodiment, the amplifier may be electrically coupled to a power supply and to an internal backup power supply. The BDA may use a UPS which has an integrated controller, charger and battery management system. In an alternative configuration, the BDA may have all three functional modules installed and wired independently to achieve the same outcome.

### BRIEF DESCRIPTION OF THE DRAWINGS

The present invention will now be discussed in further detail below with reference to the accompanying figures in which:

FIG. 1 illustrates in a schematic diagram known technology showing the functional elements in a wireless distribution configuration;

FIG. 2 illustrates in a schematic diagram presently known Technology showing the functional elements in a fiber distribution configuration;

FIG. 3 illustrates in a schematic diagram the inventive Integrated Technology showing the functional elements wireless distribution configuration;

FIG. 4 illustrates the inventive Integrated Technology showing the functional elements in a fiber distribution configuration;

FIG. 5 illustrates a first embodiment of the inventive Wireless Distributed Antenna System. showing an exemplary configuration of the constituent parts, in this case for 700 MHz-900 MHz and dual band;

FIG. 6 is a front view of a closed enclosure embodiment of the Distributed Antenna System according to the present invention

FIG. 7 is a side view of a battery array according to the present invention;

FIG. 8 is a front view of an alternative battery array according to the present invention;

FIG. 9 illustrates in a perspective view one possible electrical connection from the battery to the battery management system or UPS;

FIG. 10 illustrates in a perspective view an alternative battery array according to the present invention;

FIG. 11 shows a front view an alternative battery array according to the present invention;

FIG. 12 illustrates in a perspective view an alternative battery array according to the present invention;

FIG. 13 illustrates in a perspective view possible variants of connection cables for the battery array of FIG. 12;

FIG. 14 illustrates a second embodiment of the inventive Distributed Antenna System for use with a UHF or VHF distribution configuration in an open view according to the present invention;

FIG. 15 is another front view of a closed enclosure embodiment of the Distributed Antenna System according to the present invention;

FIG. 16 illustrates in a perspective view an alternative closed enclosure of the Distributed Antenna System according to the present invention;

FIG. 17 illustrates in a perspective view another alternative closed enclosure of the Distributed Antenna System according to the present invention;

FIG. 18 illustrates in a perspective view yet another alternative closed enclosure of the Distributed Antenna System according to the present invention; and

FIG. 19 illustrates in a perspective view still another alternative closed enclosure of the Distributed Antenna System according to the present invention;

FIG. 20 illustrates the distribution configuration of a fiber head end or remotes;

FIG. 21. illustrates another alternative embodiment closed enclosure for the fiber head end configuration of FIG. 20; and

FIG. 22 illustrated a distribution of a fiber remote closed enclosure configuration.

### DETAILED DESCRIPTION OF THE PREFERRED EMBODIMENTS

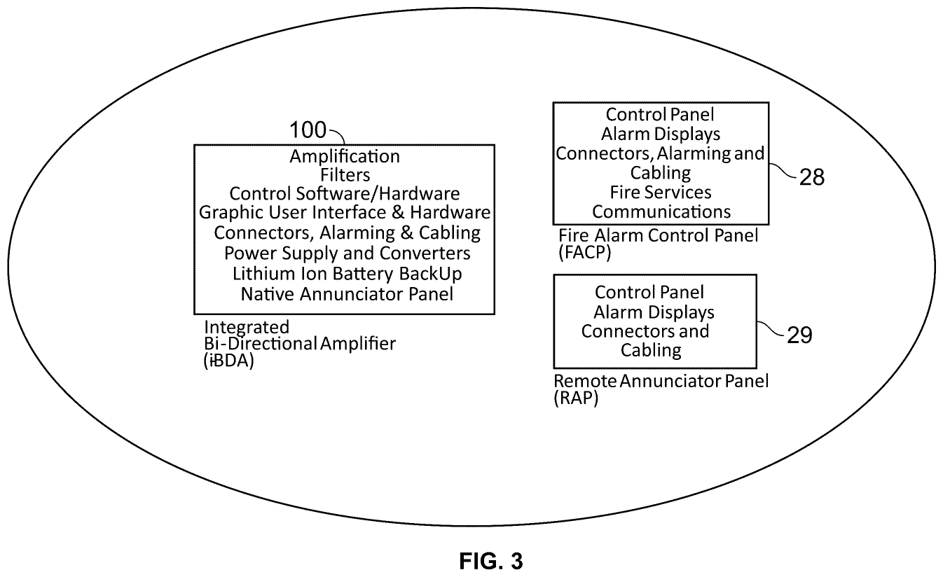

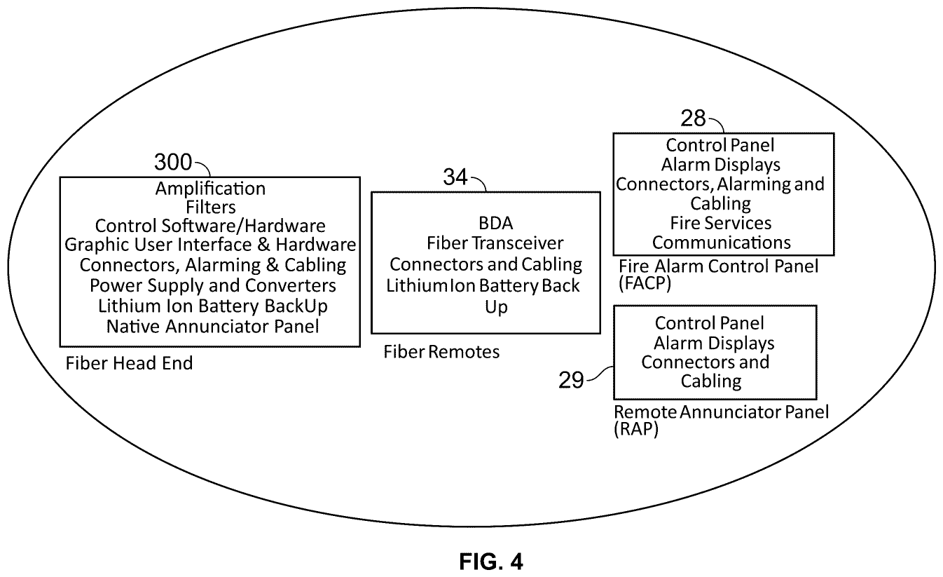

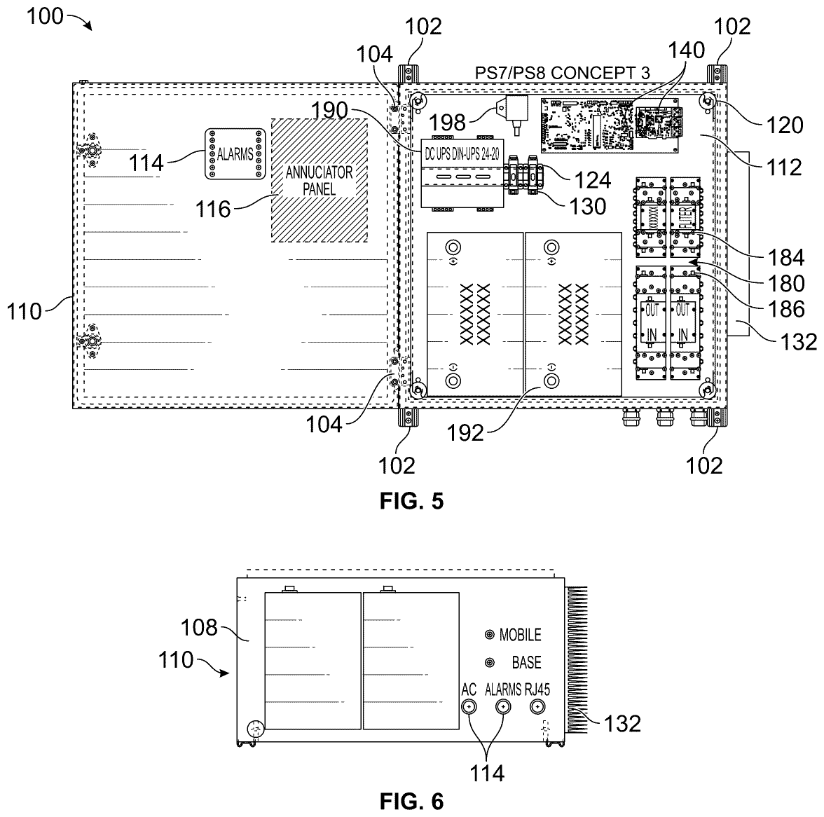

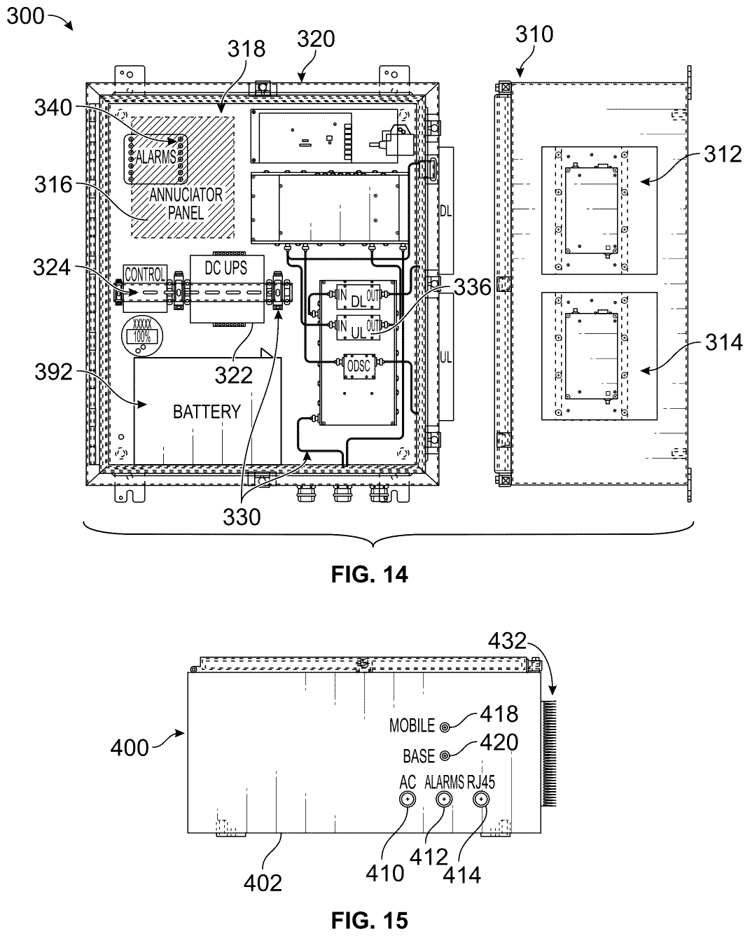

The invention as illustrated in schematic form in FIGS. 3 and 4 provides for a single unit Distributed Antenna System (DAS) enclosure 100, 300 (generally referenced also in FIGS. 5 and 14) retaining within the DAS enclosure 100, 300 an internal backup power source, such as a lithium-based, sodium ion-based or other non-lead acid battery array 192, 392 a annunciator panel 26, 116 (FIG. 5), and a bi-directional amplifier (BDA) including electronics 140, and may include other electrical components as required by the user, such as filters, control hardware, etc. The DAS enclosure 100, 300 provides a single unit that can be pre-installed, pre-connected, pre-configured, and/or pre-tested together as a unit, allowing for significantly easier and more efficient maintenance, monitoring and easier and more compact installation. Battery arrays 192, 392 optionally may also be field installed by DAS installers. Moreover, the internal power source should ideally be connected to an Uninterruptable Power Source (UPS) that can be relied upon to provide charge to the battery arrays 192, 392 to enable a back-up period of between 24 and 48 hours in emergency situations, such as disruption or loss of external electrical power that may catastrophically impact an external power source for the DAS system.

The BDA may use a UPS which has an integrated controller, charger and battery management system. An alternative configuration may have all three functional units installed and wired independently to achieve the same outcome.

The present invention and innovation provides for the reduction of the number of discreet, key functional components within the radio frequency (RF) amplification portion of a Distributed Antenna System (DAS) to a single unit module while simultaneously conveying additional benefits as further described below. It is an important feature and distinct advantage that the inventive Bi-Directional Amplifier (BDA) meets performance requirements across a range of power levels as used with associated frequency bands and complies with all relevant federal safety and regulatory requirements including those found in municipal building and fire codes, Federal Communications Commission (FCC) and overseas standards that are mandatory for each given DAS implementation.

Referring now to FIG. 5, an exemplary configuration of the DAS enclosure 100 is illustrated in which the component parts 110, 120 of the DAS are disposed in a typical layout. It should be understood that the other layouts and configurations will readily come to mind to a person having skills in BDA design and building as shown in alternative embodiment of FIG. 14, the most cogent aspect of this invention is the inclusion of the required elements within the DAS enclosure 100.

The DAS enclosure comprises two component parts 110, 120. Although section 110 is shown on the left of section 120 in FIG. 5, this is merely a convention, and the relative positions may take any shape, for example the sections 110, 120 may be mounted in a configuration vertically to each other or section 110 may be on the right side, with section 120 on the left. Indeed, and depending on the desired configuration, the two sections may be provided as a single section (not shown) with all the elements disposed therein. The two component parts 110, 120 may be joined to each other by a connector, such as hinges 104, allowing one panel or plate of one component part to cover the other component part. By attachment means, such as brackets 102, the DAS enclosure 100 can be wall or rack mounted at an appropriate location where it will be readily visible.

Referring again to FIGS. 5 and 6, section 120 includes a mounting or base plate 112, on which the several operating elements are mechanically secured. As shown in the reverse side of panel 110 in FIG. 5 and in closed and secured position in FIG. 6, the enclosure 100 has thereon disposed an external alarm and battery level display 114, as well as other communication indicators of a printed circuit board or microcontroller annunciator 116 (PCBA), all disposed on a cover 110. These elements may be in communication with other components of the Bi-Directional Amplifier (BDA) shown in the other component part 120, as will be described herein.

Section 120 preferably includes metal plates and struts, such as a DIN rail 124, that enable multi-level assembly of the other components and onto which electrical modules may be attached. For example, and as shown in FIG. 5, DIN rail 124 has attached thereon an Uninterruptible Power Supply (UPS) 190 ( ) which integrates a number of electronic servers, including a controller (not shown), a battery management system (not shown) and a battery charger (not shown). Terminal block relays 130 are electrically connected to the remaining components of the BDA, including to the annunciator panel (PCBA) 116 and to other components in both section 110 and a second section 120, such as the BDA alarm boards 140, the RF amplifier assembly 180, and other components, as described below.

Other components can be added to the DIN rail 124, for example, circuit breakers or other industrial control equipment (not shown). DIN rail 124 may comprise an electrically conductive material, e.g., metal such as stainless steel, so that it may be used as a grounding member. Alternatively, it can be nonconductive to only provide a mounting member for additional modules that can be attached thereto, as needed. A metal DIN rail 124 also may be heat conducting, and can be mechanically interface with one or more heats sinks, as described herein with reference to FIG. 6. Because the electrical components will generate significant heat from their normal operation, a method must be provided to the BDA to remove heat from the sensitive electrical components. Thus, it is preferable to use a metal heat conductive material, such as stainless steel for the DIN rail 124. Not visible in FIG. 5 is a metallic contact between the DIN rail 124, and or more of the other components, to a heat conductive path that is ultimately connected to a heat sink 132. The heat conductive path may comprise a heat conductive metal (not shown) that is capable of conducting heat away from the electronic components and to the heat sink 132. Any type of heat sink 132 is appropriate but the heat sink may be in the form of a number of adjacent fins (132, as is described below with reference to FIG. 6) that are capable to dissipate heat to the environment.

Additional components of the BDA are disposed on the mounting plate 112. These include BDA alarm boards 140, and analog or digital electronic components that are necessary to enable safe and constant operation of the device 100.

An integrated RF amplifier system 180, which may comprise a bi-directional amplifier (BDA), or similar device is disposed anywhere on the base plate 112 or mounted within close proximity of the RF analogue filter system 186 or digital filter system 140 (see section 0029). Power amplifiers 184 ideally have a power rating of at least 0.1 Watts and operate in radio frequency bands of from 30 MHz up to 6000 MHz, within which range specific bands centering on ranges of frequencies on or about 700 MHZ, 800 MHZ, 900 MHZ, UHF, VHF bands that are used for the communications for which signal amplification is provided by the DAS.

Ideally, dual bands may be used for amplifying and filtering combinations of two frequency bands being combined. Radio frequency (RF) filters 186 are required to pass specific bands or set of frequencies during the signal amplification. RF filters 186 may be mechanical, electrical or digital, including, but not limited, to RF cavity filters and notch filters, software defined radio, SDR, assemblies with Field Programmable Digital Arrays (FPGA) and programmed digital filters. Digital filters may be modified through software enabled either at the point of manufacture of the BDA or in the field through downloads made capable by the BDA technology being used.

A source of external electrical power, not shown but, for example, a direct connection to the electrical power grid, is connected to a terminal block 130 and connects to the UPS 190 which provides power toe BDA and power to the lithium-based array of batteries 192 to ensure full charge at all times and, hence, back up derived from the batteries in the event of main power failure. The UPS 190 charges one or more batteries (e.g., Lithium-ion array) integrated individually or compounded into an assembly for integration within the BDA. The battery array 192 or other source of internal power 190 is intended to begin operating instantaneously in the event of power failure or other interruption.

As is conventional in rechargeable batteries, electrical communication to the external electrical power source 190 provides a recharging capability, for example, by trickle charge or other appropriate known method of recharging. It is important to understand that all of these components are integrated into the single BDA enclosure 100, all the while meeting all technical descriptions, specifications and requirements mentioned herein, and those promulgated and required by the appropriate governing bodies.

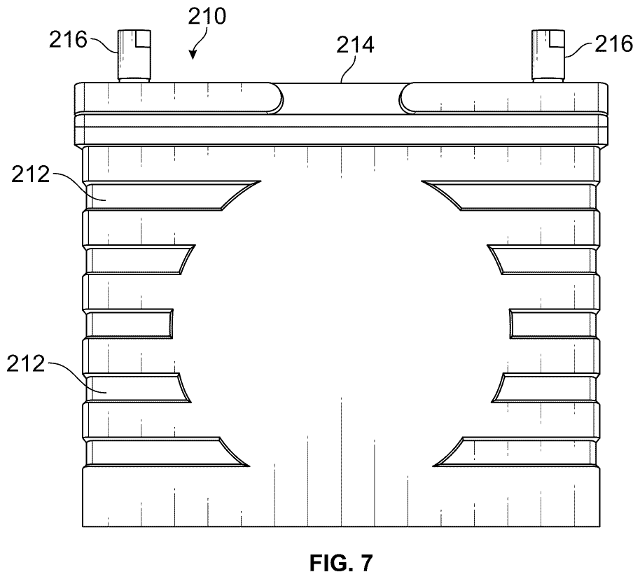

The lithium-based battery arrays 192 may comprise any of a number of configurations, as shown in FIGS. 7-12. All of the lithium battery arrays are configured, sized and oriented to fit within the enclosure 110 or 120. Optionally, the UPS 190 may include a Battery Management System (BMS) which provides pertinent information to the operators, for example, battery status, battery shelf life, and requirement of battery replacement.

A first embodiment 210 of the lithium-ion battery array 192 is shown in FIG. 7. It illustrates a stack of battery cells 212 that may be enclosed by a housing 214. Fixed electrical contacts 216 provide electrical power to the rest of the system within the BDA when power is interrupted or fails.

As described, the battery array 192 does not normally provide electrical power to the system, which is provided by the external power source connected to the terminal blocks described above. When external power is available, the only operation that the internal battery array 192 performs is to retain the connection to the UPS 190 and so to maintain a full charge and thus be ready to operate in the event a power disconnection or interruption. In that event, the Lithium-ion battery array 192 becomes the primary power source for the BDA and continues to do so for a period until external power is restored. It is noted that the electrical configuration enabling the system to rely on the internal power from the UPS 190 may be conventional, or may be customized depending on the requirements of the end user.

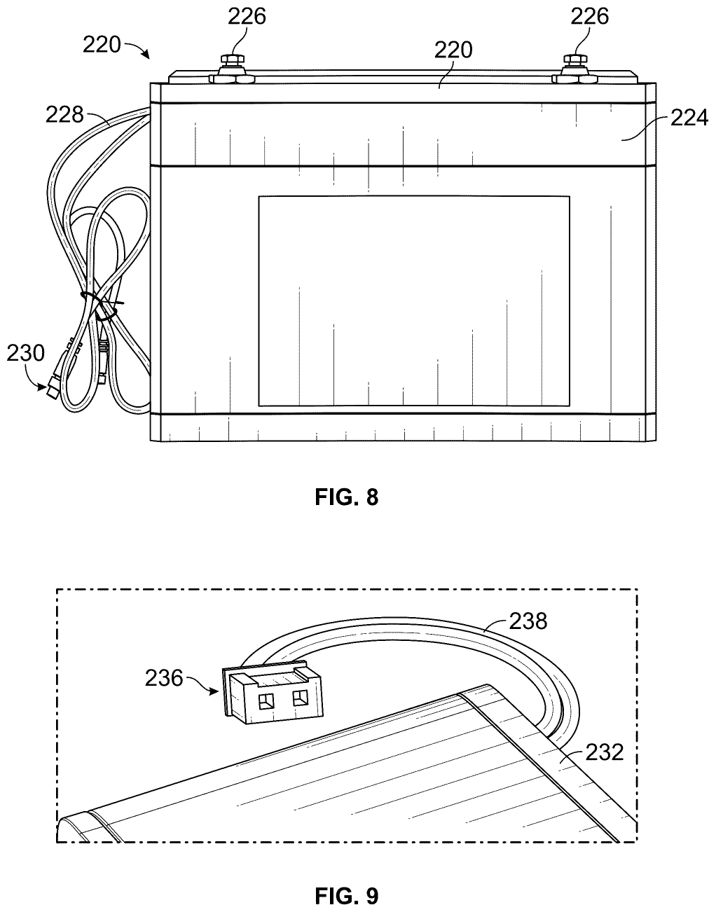

A second embodiment 220 of the battery array 192 is shown in FIG. 8. The cells (not shown) are disposed within an enclosure or housing 224 which may be made preferably of a hard plastic or thermoplastic polymer, such as Acrylonitrile butadiene styrene (ABS) or Polypropylene. Electrical communication may be provided by either fixed contacts 226 or by a cable 228 having detachable screwed contacts 230. As shown in yet another alternate embodiment in the detail of FIG. 9, the detachable screwed contacts may be replaced by snap fit electrical connections 236 connected to the battery 230 by a cable 238. These may be standard electrical connections that may provide contact with other electrical components of the system, e.g., to the UPS 190.

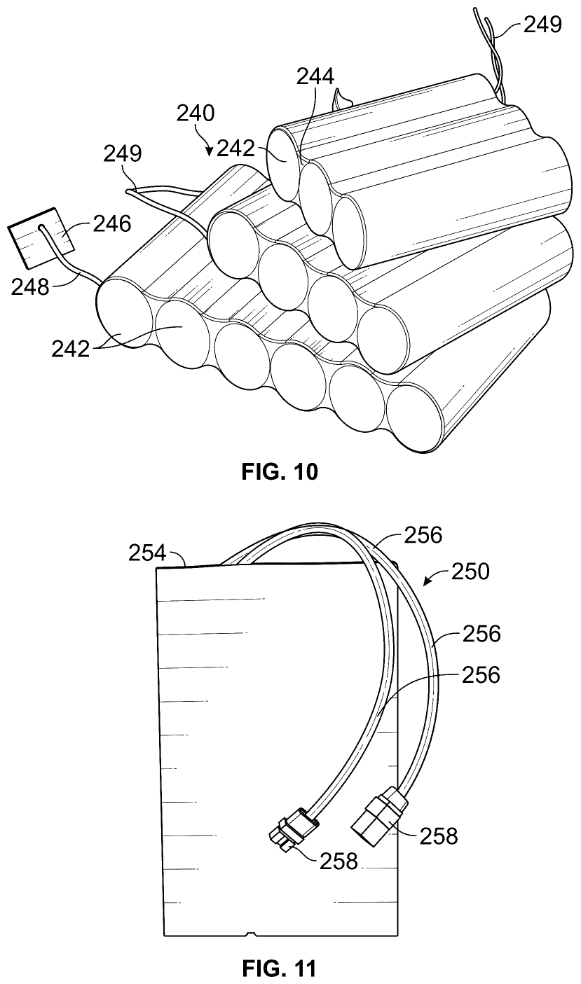

The UPS 190 may be connected to a Lithium-Ion battery array 240 as shown in FIG. 10. Array 240 may consist of a number of battery cells 242 collectively connected with the UPS, either in series or parallel, as required. The battery cells 242 are preferably enclosed and maintained in close proximity to each other by shrink wrapping 244. The battery array 240 is connected to the rest of the system by means of a cable 248 having a snap fit connection 246, or simply by a wired connection 249.

As shown in FIG. 11, the battery 192 may comprise another embodiment battery array 250 including internal battery cells (not shown) enclosed within a housing 250. The battery array 240 includes one or more external cables 256 having snap fits connection 258.

As illustrated in FIG. 12, the battery array 260 may have an integrated battery management system (BMS) 262 with a data port 261 for providing electrical connection to other components of the system. There is a rigid enclosure 264 as shown. An alternate enclosure is shrink wrapping 244 (FIG. 10) of cells where there would be separate wires for power conductivity and data transmission (not shown). Connections for data from the battery 260 to the UPS 190 may be through RJ45 type cables 270 having connectors 272, or alternatively, by USB data cables 274 with connectors 276. Power, charging and back up purposes, may be connected via screw or bolt connectors 266.

The lithium-ion battery arrays 192 described above may comprise any of a number of known lithium-ion or metal-ion battery technologies. These include Lithium Iron Phosphate, Lithium Cobalt Oxide, Lithium Manganese Oxide, Lithium Nickel Manganese Cobalt Oxide, Lithium Nickel Aluminum Cobalt Oxide, Lithium Titanate and Sodium Ion based technologies or other batteries made with appropriate known energy transition metallics and compounds. Ideally, the expected working lifetime of the battery array 192 is in the range of from 8-15 years with many manufacturers providing warranties from 10 year upwards.

The Bi Directional Amplifier 100 is preferably electrically coupled to an external primary power source as well as an internal backup power supply. The backup power supply may be a lithium-based battery array, as opposed to a lead acid battery that has been used in standard configurations of this type. The lithium-based battery array may, for example, be connected to the amplifier by a controller contained within the UPS 190,

Referring again to FIGS. 5 and 14, the Lithium-Ion battery array 192 392 is connected to the UPS 190 322 which activates various failure and warning alarms. The UPS is connected via wiring (not shown) to the annunciator panel 116, 316 which in turn is connected to the built-in annunciator display 114 340. As per NFPA code, the battery array alarms provide threshold indicators for failure modes, such as AC Power Fail, Battery charger fail and low battery 30% threshold. The lithium-based battery array 192, UPS 190, annunciator panel 116 and annunciator display 114 may, for example, be integrated into a single DAS enclosure meeting one of the specifications mentioned herein.

The lithium-based battery array 192, UPS 190, and amplifier array 180 is preferably contained within a dedicated housing and can be pre-installed, pre-connected, pre-configured, and/or pre-tested together as a single unit as a single DAS enclosure 100. The backup battery array 192 may be miniaturized or customized to suit different sizes of DAS enclosure and provide backup requirements (e.g., 12 hours, 24 hours or more using one or more individual batteries) as required for a given installation according to building or fire codes for that installation. Depending on each specific installation per building and fire codes, the BDA, as well as its internal alarm display 114, may be connected and electrically wired to an external fire alarm system, e.g., the fire alarm control panel FACP 28 (FIGS. 3, 4).

The DAS enclosure may comprise walls of metal, resin or plastic with requirements subject to fire and building safety codes for a specific installation that vary but may be conducive to penetration of wireless signal or RF bands. It is preferable that the DAS be NEMA rated, IP Rated, Type (UL) Rated Rack Mount and other non NEMA/IP type ratings, as required by local codes. DAS enclosures are integrated with heatsinks, passively cooled through convection or conduction hardware such as attached finned heat exchanger plates or fins molded into the DAS enclosure, and mounting plates for the various components, or alternatively, may be actively cooled, using cooling media such as water. The DAS enclosure may have a built-in annunciator panel, with alarm displays and notifications, and connect to external annunciator panels depending on required installation configurations according to building and fire codes.

Different embodiments may be configured depending on the requirements of a specific installation or as required by regulatory bodies, e.g., federal, FCC, building codes or municipal regulations. Ideally, the configurations specified will provide benefits to the installation process, e.g., allowing an installer to advantageously install a single DAS enclosure containing the amplifier, the lithium-based battery array, the UPS and annunciator panel without requiring individual purchase, assembly, and/or testing. Such installation also benefits from the reduction in the surface area required for installation, in the materials required for implementation and labor required for installation, and in reducing the trouble shooting resources and tuning required for installation.

The inventive Bi Directional Amplifier has an alternative configuration 300 that is designed to accommodate an Ultra High Frequency (UHF) and Very High Frequency (VHF) regime, as illustrated in FIG. 14. There is also in this configuration a dual section layout, including a first section 310 and a second section 320. The first section 310 includes electronic components 312, 314 performing the tasks of RF signal amplification. Section 320 includes DIN rail 324 connected to the UPS 322 to which there are attached thereon, a controller 324 (note alternative configuration to FIG. 5), a charger (not shown) and one or more terminal block relays 330. The UPS 322 is electrically connected to the remaining components of the BDA, including to the annunciator panel 316, alarm display 340, the amplifier array 312, 314, 380, and other components by means of internal wiring 362.

The BDA is preferably electrically coupled to an external primary power source as well as an internal backup power supply provided by the UPS 390, in this case provided by a lithium-ion battery array 392. The lithium-based battery 392 may, for example, be connected to the amplifier array by the UPS 322 described above. The UPS 322 The Lithium-Ion battery array 392 is connected to the UPS 190 which activates various failure and warning alarms. The UPS is connected via wiring to the annunciator panel 316 which in turn is connected to the built-in annunciator and alarm display 340. As per NFPA code the battery array alarms provide threshold indicators for failure modes, such as AC Power Fail, Battery charger fail and low battery 30% threshold. The lithium-based battery array 392, UPS 322, annunciator panel 316 and annunciator display 340 may, for example, be integrated into a single DAS enclosure 300 meeting one of the specifications mentioned herein.

The DAS sections 110, 120; 310, 320 and any other configurations that may be the subject of a design or layout of the Bi-Directional Amplifier are enclosed within a housing 400 as shown in FIG. 14. The two sections 110, 120; 310, 320 of each BDA 100, 300 (or indeed any other configurations) comprise one of the configurations as exemplified in FIGS. 6 and 15 which operates as a base, and then is enclosed by a cover plate 402 within the housing 100, 300 made of sheet metal or cast aluminum. The cover plate 402 may be attached to the base by an appropriate attachment means, such as bolts (not shown). Alternately, the cover may be hinged at one end thereof so that unlocking the housing 400 can then provide access to the two sections 110, 120 (and 310, 320, when configured in that layout) for repair and updating or other operations, as needed. The dimensions and shape of the cover plate 402 match the base dimensions so that the cover plate 402 completely encloses the BDA 100, 300.

Cover plate 402 has certain features, such as apertures through which components such as connectors, wiring conduits and power connectors are inserted. Referring to FIG. 15, as an illustration, three electrical connectors are shown 410, 412, 414 each having individual functions within the operation of the BDA and the external environment. Connectors 418, 420 are examples of RF input and output connectors for the BDA. The cover plate 402 is electrically connected to the electrical components within the housing 400 and includes means for communication with the electronic components, generally by wired connections. The connector 410 provides for external AC power from an external power source typically tied to the building circuitry (not shown). Connector 412 provides for a cable to attach to/from the annunciator panel 316 to the fire alarm control panel 28. (FIG. 4). Connector 414 is a communications port, RJ45 type, enabling the installer to access the Graphic User Interface (GUI) software of the BDA to configure the BDA as needed from the installer's laptop or remote computer.

The connectors 410, 412, 414 are allowed communication through the cover 402 at appropriate apertures through which the components extend. To maintain a water tight seal of the housing 400, as is required by regulations, e.g., NEMA 4, the connectors 410, 412, 414 include gaskets (not shown) to prevent water ingress into the housing 400. The connectors that may be utilized may take any of a number of forms, such as RJ45 connectors for engaging electrical signals. Other connectors 410 may provide connections to the internal components, such as to the external primary power source, fire alarm panels outside the housing 400, etc.

The housing 400 may alternatively be made of metal walls to which the mounting panel 120, 320 may be attached to provide a multi-level configuration. A heat exchanger (not shown) in direct physical contact with the electronic components may extend beneath the mounting panel 112, 318 toward the aperture so as to make direct contact with the amplifier filter assembly at one end and a heat sink at the other.

As described above, the cover includes a heat sink, which may take the form of fins 132, 432 that provide heat transfer from the internal electronics by passive heat dissipation into the environment external to the enclosure. The fins 132, 432 are typically made of aluminum that is block cast into a mold to create the ridges, as shown. The fins 132, 432 as an assembly are mechanically attached to one or more ends of the enclosure. The housing 400 wall may include a cut out aperture through which a heat exchanger (not shown) may be inserted to provide a pathway for excess heat generated by the internal electronic components, such as the amplifier assembly 180, 380. A gasket may be placed between the heat exchanger and the aperture to retain a fluid tight seal at the aperture. Alternately, fins 132, 432 may be cast and manufactured simultaneously with the housing 400 and include an integral heat exchanger in the housing 400.

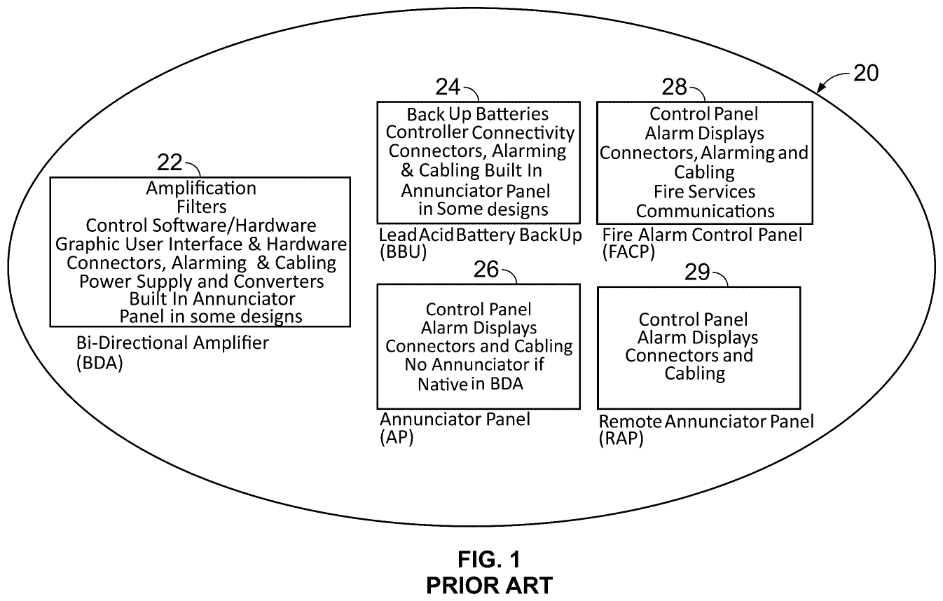

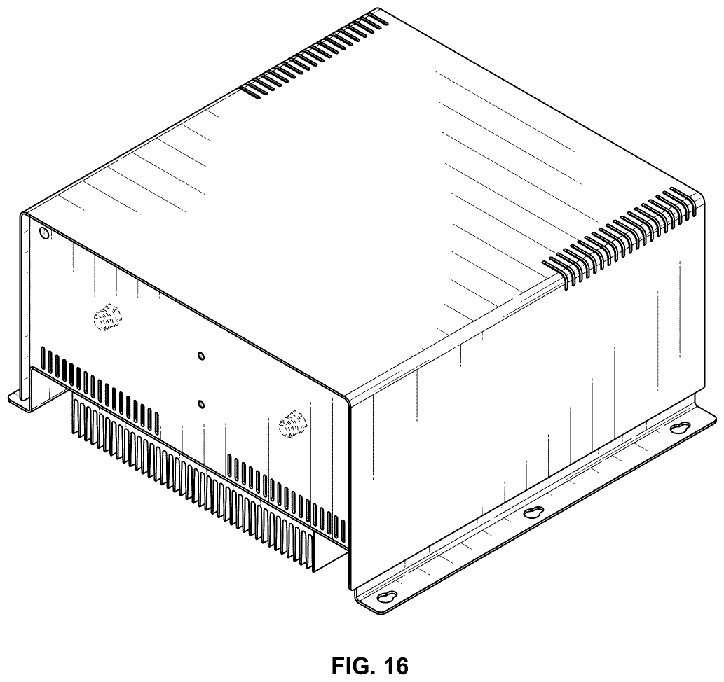

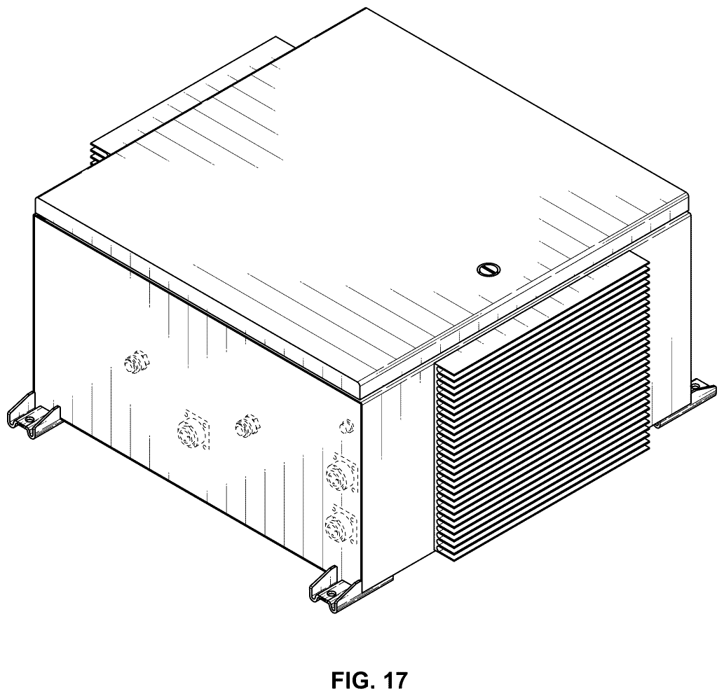

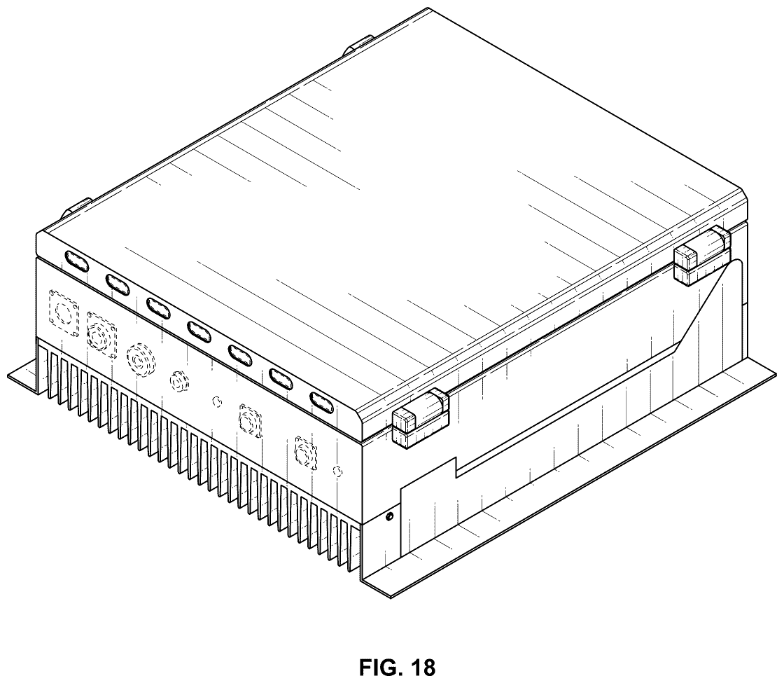

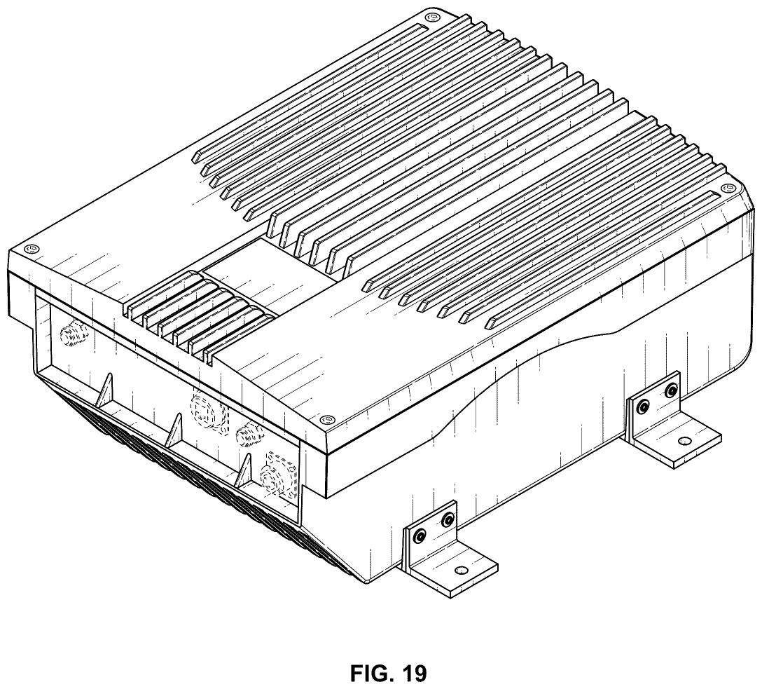

While a certain configuration of the outer surface of the cover 108, 402, but that configuration may take any of a number of different layouts which do not comprise any significant inventive features. Other similar configurations of the cover 108, 402 are possible. For example, several alternate configurations of the cover are disclosed in four commonly-owned and concurrently filed design patent applications. Specifically, the following Design patents application Ser. Nos. 29/949,068; 29/949,077; 29/949,086; and Ser. No. 29/949,099, all filed on even date herewith, and the illustrations and disclosures of which are fully incorporated as if described and illustrated herein. The perspective views (FIG. 1) of each of the design patent illustrations are shown herein as FIGS. 16-19. The individual features shown in these features, e.g., the cover plate, fins, etc., are not individually described, but they have similar structures and perform similar functions as the ones shown in FIGS. 6 and 15. The invention thus does not lie in the specific configuration, but in the ability to pre-manufacture the inventive BDA 100, 300 as a single complete enclosure containing within the housing all of the electronic components that provide communications between the location where the BDA is disposed and an external node monitoring and/or control center and/or a network operations control (NOC) is in communication therewith.

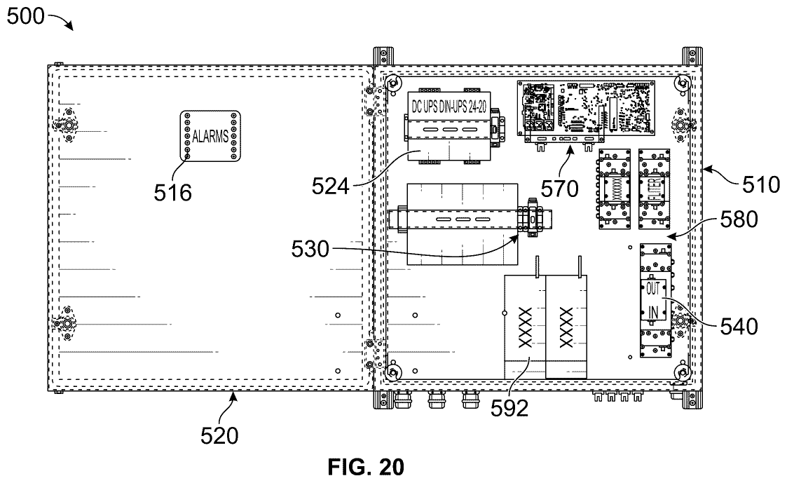

Another alternative embodiment 500 of the inventive configuration of a BDA is illustrated in FIG. 20 and provides for a fiber head end unit or remote 510. As many of the internal electronic elements are identical or similar to those in FIGS. 5 and 14, they will not be described individually here. Retaining within the enclosure 510, 520 is an internal backup power source 592, as described with reference to similar backup power sources 192, 392 above, such as a lithium-based, sodium ion-based or other non-lead acid battery array 592, an annunciator panel 516, a bi-directional amplifier (BDA) including electronics 540, and RF to light converter (FOTX) 570, may include other electrical components as required by the user, such as filter array 580, control hardware 540, etc.

The DAS enclosure provides a single unit that can be pre-installed, pre-connected, pre-configured, and/or pre-tested together as a unit, allowing for significantly easier and more efficient maintenance, monitoring, connecting to multiple fiber remotes, and easier and more compact installation. Battery arrays 592 optionally may also be field installed by DAS installers. Moreover, the internal power source should ideally be connected to an Uninterruptable Power Source (UPS) 524 that can be relied upon to provide charge to the battery arrays to enable a back-up period of between 12 and 24 hours in emergency situations, such as disruption or loss of external electrical power that may catastrophically impact an external power source for the fiber headend unit system 500.

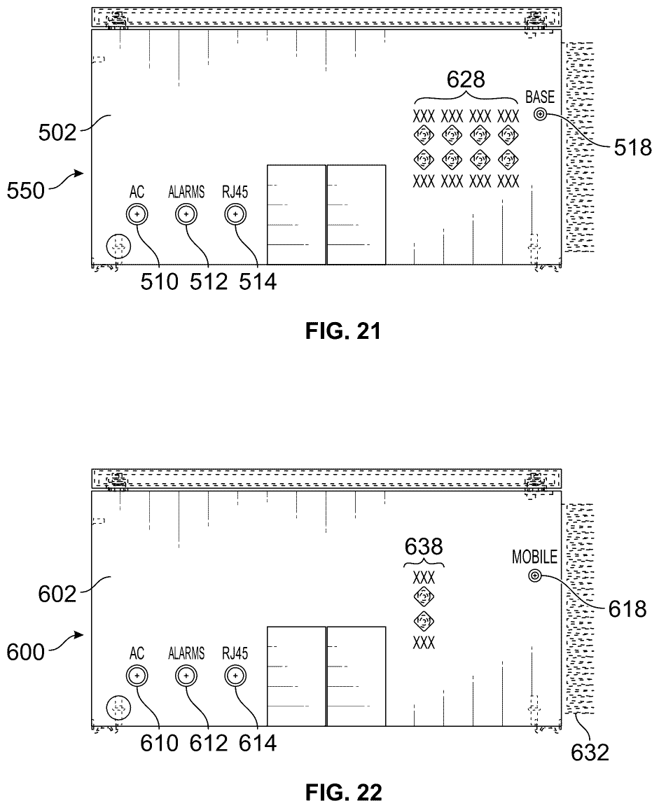

With reference to FIG. 21, there is shown a housing 550 having a cover plate 502, including three electrical connectors are shown 510, 512, 514 each having individual functions within the operation of the BDA and the external environment. Connector 518 is RF input connectors for providing communications to the BDA. The cover plate 502 is electrically connected to the electrical components within the housing 550 and includes means for communication with the electronic components, generally by wired connections. The connector 510 provides for external AC power from an external power source typically tied to the building circuitry (not shown). Connector 512 provides for a cable to attach to/from the annunciator panel 516 to the fire alarm control panel 28. (FIG. 5). Connector 514 is a communications port, RJ45 type, enabling the installer to access the Graphic User Interface (GUI) software of the BDA to configure the BDA as needed from the installer's laptop or remote computer. Fiber Connectors 628 distribute communications via light signals to remotes 600, as shown in FIG. 22, where the remote units 600 convert light signals back to radio frequencies.

The invention as illustrated in FIG. 22 provides for a fiber remote unit 600 as shown. The component parts internal to the enclosure cover 602 being identical to those described above and illustrated in FIG. 20. Thus, reference is made to FIG. 20 for the internal components the differences in the external cover configuration 600 being shown and described herein. The remaining connectors in the cover plate 602, that is, connectors 610, 612, and 614 are identical to those of FIG. 21 and will not be further discussed herein. Connector 618 provides external communications to the BDA through a mobile connection. Fiber connectors 638 receive communications via light signals from the head end as shown in FIG. 21. Remote units convert the light signals back to radio frequencies via the FOTX 570.

The various embodiments and configurations illustrated and described herein materially reduce, by a minimum of 25%, the size and weight of known DAS enclosures while achieving performance requirements, the number of modules to be installed, the surface area required for installation, the materials required for implementation, the labor required for installation, and the tuning required for installation. These benefits are all appreciated by those skilled in the art and by installers of these types of devices. Simultaneous advantages and benefits arise in use of the Integrated BDA by providing a single integral unit that can communicate through a distributed antenna system even in the event of a power outage (e.g., an emergency).

The Integrated BDA according to the present invention will comply with all applicable building and fire code standards such as NFPA1225, IFC22024, IFC2021, UL2524 (2nd Edition), including codes currently evolving for 2027, such as NFPA, IFC, UL 3rd Edition currently under discussion by review boards. Further compliance with the FCC Part 90, similar, comparable overseas standards (e.g. including but not limited to Industry Canada, ISED Canada, CE Standards for the EU, Ofcom in the UK, LARGC covering South America, Unicom in China, FCT Mexico, KCC in Korea, MRA in Japan and ACMA in Australia) and to meet UL2524 (2nd Edition) including key components making up the integrated BDA.

It should be noted that the Integrated BDA described above provides great flexibility in allowing different configurations as the technology applies to wireless, e.g. land mobile radio, cellular and fiber signal boosting and distribution within any given environment.

The batteries used in the integrated BDA, including a fiber distributed solution, provide approximately double the life of batteries in the known, non-integrated configurations. This confers a lower cost of ownership to the building owner and a lower cost of maintenance to the installer.

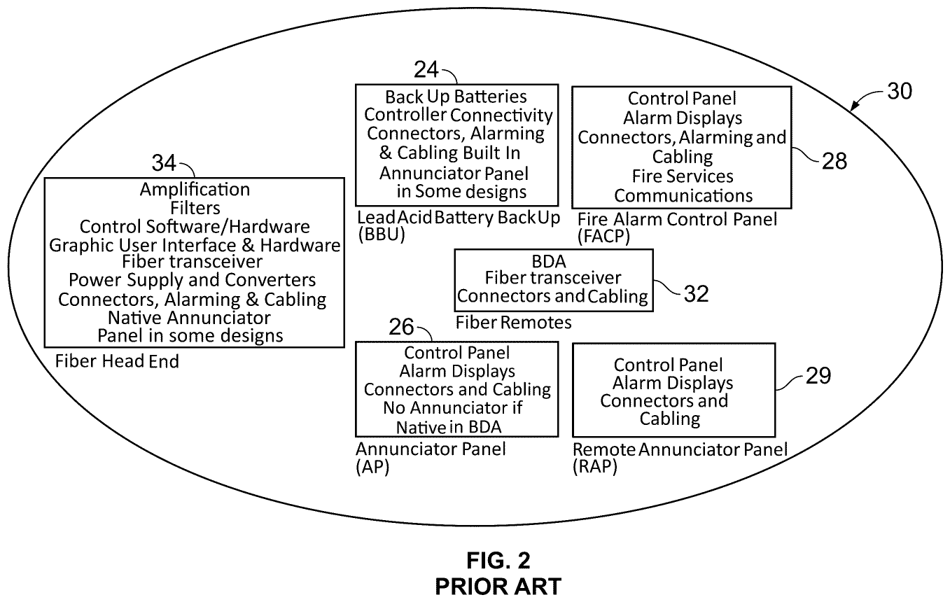

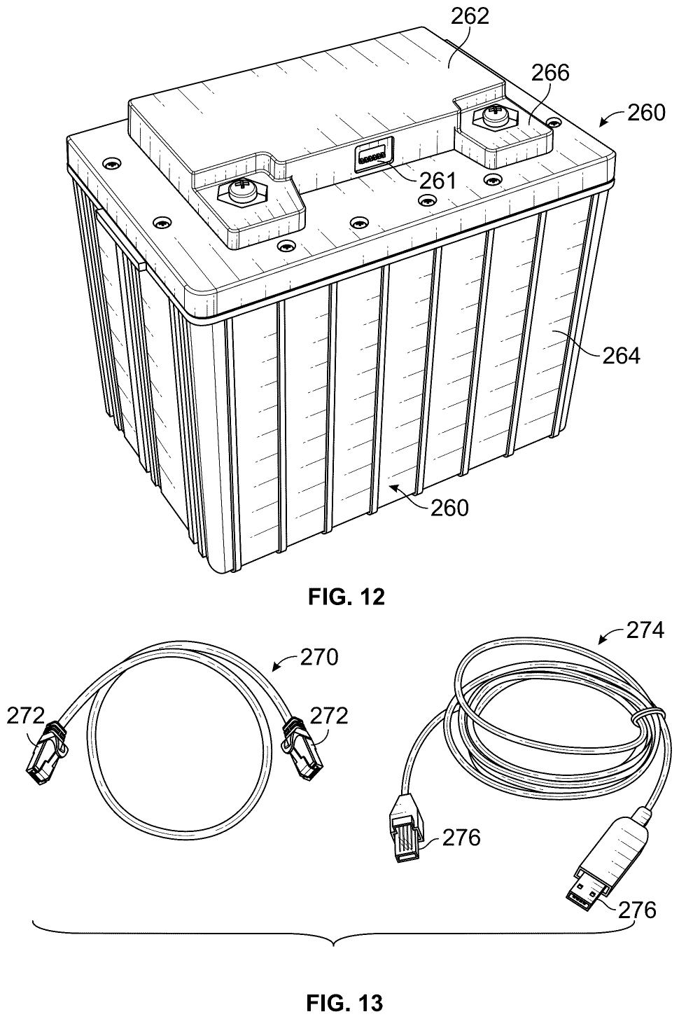

The invention herein has been described and illustrated with reference to the embodiments of FIGS. 1-22, but it should be understood that the features and operation of the invention as described is susceptible to modification or alteration without departing significantly from the spirit of the invention as disclosed above. While such systems are shown in exemplary fashion, other configurations will readily come to mind to a person having ordinary knowledge of the art, including of local standards, building codes, fire codes, NICET (National Institute for Certification in Engineering Technologies) or experienced installers, as well as RF expertise. For example, the dimensions, size and shape of the various elements may be altered to fit specific applications, as described above. Accordingly, the specific embodiments illustrated and described herein are for illustrative purposes only and the invention is not limited except by the following claims.

What is claimed is:

1. A unified, integrated bi-directional Radio Frequency (RF) amplifier comprising
a) a unitary housing having walls adapted to allow communication therethrough;
b) a power amplifier;
c) an analog or digital radio frequency signal filter; and
d) an external primary power source and an internal electrical backup power source,
wherein the power amplifier, the radio frequency filter and the internal electrical backup power source are integrated within a BDA all enclosed by the unitary housing.

2. The unified, integrated bi-directional RF amplifier according to claim 1 including a battery management system, a battery charger, a controller which may be combined in a uninterruptible power source or as separate units all of which may or may not be mounted on a DIN rail or separately mounted within the BDA.

3. The unified, integrated bi-directional RF amplifier according to claim 1 wherein the housing walls include at least one aperture adapted for providing electrical communications therethrough.

4. The unified, integrated bi-directional RF amplifier according to claim 1 wherein the housing walls include at least one aperture adapted for providing fiber optic communications therethrough.

5. The unified, integrated bi-directional RF amplifier according to claim 1 wherein the housing walls include a material adapted for providing wireless communications therethrough.

6. The unified, integrated bi-directional RF amplifier according to claim 1 wherein the housing walls comprise a material selected from one or more of the group consisting of metal, resin or plastic, which material is adapted to permit wireless communications therethrough.

7. The unified, integrated bi-directional RF amplifier according to claim 1 wherein the power amplifier is adapted to amplify at least one band and has a power rating of at least 0.1 Watts.

8. The unified, integrated bi-directional RF amplifier according to claim 1 wherein the power amplifier is adapted to amplify single and dual bands.

9. The unified, integrated bi-directional RF amplifier according to claim 1 wherein the power amplifier operates in frequency bands in a range from about 30 to about 40,000 MHz for both telecom, high reliability (land, sea, air, space for military and commercial space applications).

10. The unified, integrated bi-directional RF amplifier according to claim 1 wherein the RF signal filters are selected from the group consisting of one or more of mechanical signal filters, RF cavity filters, notch filters, digital filters and software defined radio (SDR) assemblies with Field Programmable Digital Arrays (FPGA) programmed with digital filters.

11. The unified, integrated bi-directional RF amplifier according to claim 10 wherein the digital filters are adapted to receive updates of software enabled during manufacture of the Bi-Directional Amplifier.

12. The unified, integrated bi-directional RF amplifier according to claim 10 wherein the digital filters are adapted to receive updates of software in the field through downloads within a distributed antenna system Bi-Directional Amplifier.

13. The unified, integrated bi-directional RF amplifier according to claim 1 wherein the internal electrical backup power source further comprises a lithium-ion battery.

14. The unified, integrated bi-directional RF amplifier according to claim 13 wherein the lithium-ion battery is selected from one of the group consisting of a Lithium Iron Phosphate battery, Lithium Cobalt Oxide battery, Lithium Manganese Oxide battery, Lithium Nickel Manganese Cobalt Oxide battery, Lithium Nickel Aluminum Cobalt Oxide battery, and Lithium Titanate battery and Sodium Ion battery technologies or any energy transition metallic compound based battery technology.

15. The unified, integrated bi-directional RF amplifier according to claim 1 wherein the backup electrical power supply comprises a lithium-ion battery array connected to the UPS

16. The unified, integrated bi-directional RF amplifier according to claim 15 wherein the UPS unit is adapted to provide electrical power, current, voltage, charge and discharge and alarming characteristics of the lithium-ion battery array connected to the amplifier. The functions of the UPS may also be fulfilled but discreet, individual components.

17. The unified, integrated bi-directional RF amplifier according to claim 15 wherein the wherein the amplifier is adapted to communicate externally of the housing wirelessly.

18. The unified, integrated bi-directional RF amplifier according to claim 15 wherein the wherein the amplifier is adapted to communicate externally of the housing by at least one fiber optic cable.

19. The unified, integrated bi-directional RF amplifier according to claim 18 wherein the wherein the RF to light and a Light to RF converter unit includes a converter to convert a signal from the at least one fiber optic cable to a radio frequency signal.

20. A method of installing a unified, integrated bi-directional Radio Frequency (RF) amplifier comprising
a) providing a unitary housing having walls adapted to allow communication therethrough, the housing containing within the walls a power amplifier, an analog or digital radio frequency signal filter, and an internal electrical backup power source;
b) connecting the RF amplifier to a source of external electrical power through electrical connectors extending through walls in the housing; and
c) connecting communication means through communication connectors extending through walls in the housing.
